(19) United States
(12) Patent Application Publication
(10) Pub. No.: US 2025/0253618 A1
(43) Pub. Date: Aug. 7, 2025

(54) Method for operating a laser device and laser device

(71) Applicant: ams International AG, Jona (CH)

(72) Inventors: Karolina TRACZYK, Bursins (CH); Michael BÖHM, Graz (AT)

(21) Appl. No.: 18/854,974

(22) PCT Filed: Apr. 24, 2023
(86) PCT No.: PCT/EP2023/060618

§ 371 Date: Oct. 8, 2024

(30) Foreign Application Priority Data
Apr. 25, 2022 (DE) 102022109837.0

(51) Int. Cl. H01S 5/0683; H01S 5/06; H01S 5/068

(52) U.S. Cl. CPC H01S 5/06837; H01S 5/0617; H01S 5/06804; H01S 5/06808

(57) ABSTRACT

A method for operating a laser device is provided, the method comprising providing an emitter structure of the laser device with a first amount of power by a driving circuit of the laser device. The emitter structure is configured to emit laser radiation during operation, extrapolating the temperature of the emitter structure. Extrapolating the temperature of the emitter structure includes receiving a temperature value measured for the emitter structure provided with the first amount of power during a calibration phase and providing the emitter structure with a second amount of power by the driving circuit. The second amount of power corresponds to the power required for the emitter structure emitting a target intensity of laser radiation at the extrapolated temperature. Furthermore, a laser device is provided.

### CROSS-REFERENCE TO RELATED APPLICATION(S)

This application is a national phase of International Patent Application No. PCT/EP2023/060618 filed on Apr. 24, 2023, which claims priority to German Patent Application No. 102022109837.0 dated Apr. 25, 2022, the contents of both of which are incorporated fully herein by reference.

### TECHNICAL FIELD

A method for operating a laser device and a laser device are provided.

### BACKGROUND

For laser devices it is often desired to monitor the temperature of the emission region since some properties of laser devices depend on the temperature of the emission region. For example, the threshold current and the slope of the output power over current curve of a laser device depend on the temperature of the emission region. Thus, for different temperatures of the emission regions different driving currents might be required to achieve the same output intensity. After measuring the temperature, the driving current can be adjusted accordingly.

It is an objective to provide a method for operating a laser device with an improved accuracy. It is further an objective to provide a laser device that can be operated with an improved accuracy.

These objectives are achieved by the subject matter of the independent claims. Further developments and embodiments are described in dependent claims.

### BRIEF DESCRIPTION OF THE DRAWINGS

The figures and following description may further illustrate and explain exemplary embodiments. Components that are functionally identical or have an identical effect are denoted by identical references. Identical or effectively identical components might be described only with respect to the figures where they occur first. Their description is not necessarily repeated in successive figures, which figures include:

FIG. 1 an exemplary embodiment of the method for operating a laser device is described;

FIG. 2 is another exemplary embodiment of the method for operating a laser device is described;

FIG. 3 shows another exemplary embodiment of the method for operating a laser device is described;

FIG. 4 shows an exemplary embodiment of the laser device;

FIG. 5 shows another exemplary embodiment of the laser device; and

FIG. 6 schematically shows the output power of a laser device at different temperatures.

### DESCRIPTION

According to at least one embodiment of the method for operating a laser device, the method comprises providing an emitter structure of the laser device with a first amount of power by a driving circuit of the laser device, wherein the emitter structure is configured to emit laser radiation during operation. The emitter structure can comprise an active region of the laser device. Once provided with power the emitter structure can be configured to emit electromagnetic radiation. The emitter structure can comprise a cavity. It is also possible that the emitter structure comprises a ridge structure that is configured to emit electromagnetic radiation during operation. The emitter structure can be configured to emit laser radiation during operation of the laser device. The emitter structure can be configured to emit laser radiation once provided with electric current. The driving circuit can be configured to provide the emitter structure with power. It is also possible that the driving circuit is configured to provide the emitter structure with electric current. The driving circuit can comprise a power source and/or a current source. The first amount of power relates to a first current provided by the driving circuit to the emitter structure.

According to at least one embodiment of the method for operating a laser device, the method comprises extrapolating the temperature of the emitter structure, wherein extrapolating the temperature of the emitter structure comprises receiving a temperature value measured for the emitter structure provided with the first amount of power during a calibration phase. That the temperature of the emitter structure is extrapolated can mean that a future temperature of the emitter structure is calculated, predicted or estimated. It is also possible that extrapolating the temperature of the emitter structure means that a current temperature of the emitter structure is calculated, predicted or estimated. The extrapolation of the temperature can be based on pre-recorded data of the laser device. The extrapolation of the temperature of the emitter structure can be carried out by an algorithm.

Before operating the laser device, a calibration phase is carried out. During the calibration phase the laser device can be characterized with respect to different parameters. During the calibration phase the emitter structure is provided with the first amount of power. At the same time the temperature of the emitter structure is determined. The information which temperature was determined for the case that the emitter structure is provided with the first amount of power can be saved in a database. Another measurement which can be carried out during the calibration phase can be the measurement of at least one light-current-voltage (LIV) curve for the emitter structure. Also the data obtained in this measurement or other data obtained during the calibration phase can be saved in the database. The information saved in the database can be employed for extrapolating the temperature of the emitter structure. It is also possible that the wall plug efficiency of the emitter structure is determined during the calibration phase.

According to at least one embodiment of the method for operating a laser device, the method comprises providing the emitter structure with a second amount of power by the driving circuit, wherein the second amount of power corresponds to the power required for the emitter structure emitting a target intensity of laser radiation at the extrapolated temperature. The emitter structure can be provided with the second amount of power after the emitter structure has been provided with the first amount of power. The second amount of power can be different from the first amount of power. The target intensity can be an intensity of laser radiation that the emitter structure or the laser device is desired to emit. Thus, the target intensity can be a predefined value. The target intensity can be chosen in such a way, that overheating of the emitter structure is avoided. The target intensity can be proportional to an optical pulse energy of laser radiation emitted by the emitter structure. The second amount of power is given by the condition that the emitter structure emits laser radiation of the target intensity while the emitter structure has the extrapolated temperature when the emitter structure is provided with the second amount of power. This can mean, that the second amount of power is determined under the assumption that the emitter structure the extrapolated temperature.

According to at least one embodiment of the method for operating a laser device, the method comprises providing an emitter structure of the laser device with a first amount of power by a driving circuit of the laser device, wherein the emitter structure is configured to emit laser radiation during operation, extrapolating the temperature of the emitter structure, wherein extrapolating the temperature of the emitter structure comprises receiving a temperature value measured for the emitter structure provided with the first amount of power during a calibration phase, and providing the emitter structure with a second amount of power by the driving circuit, wherein the second amount of power corresponds to the power required for the emitter structure emitting a target intensity of laser radiation at the extrapolated temperature.

The method for operating a laser device is based inter alia on the idea that the intensity of laser radiation emitted by the emitter structure depends on the temperature of the emitter structure. For example if the emitter structure heats up a larger amount of power or a higher current is required to achieve the same intensity of emitted laser radiation as before. Thus, it is necessary to adapt the power provided to the emitter structure for the case that the temperature of the emitter structure changes if it is desired to achieve the same emitted intensity or to achieve a target intensity. In particular, the laser threshold current and the slope efficiency depend on the temperature of the emitter structure. Thus, a change in the temperature of the emitter structure can even lead to the provided current being below the threshold current so that no lasing is achieved.

For many laser devices the frequency of providing laser radiation or laser radiation for different pixels of an image is significantly higher than possible rates of temperature measurements. This means, in many cases the temperature of an emitter structure cannot be measured as often as a new laser pulse is provided by the emitter structure. Thus, for a plurality of laser pulses, namely the laser pulses provided between two temperature measurements, the amount of power provided to the emitter structure cannot be adapted to a change in the temperature of the emitter structure. This can lead to the emission of laser radiation with an intensity that is different from a desired value of intensity. This can also lead to the emission of laser radiation with a wavelength that is different from a desired wavelength.

The method described herein enables to adapt the amount of power provided to the emitter structure in view of a changed temperature of the emitter structure at a higher rate. This can mean, that the amount of power provided to the emitter structure is corrected. For this purpose, the temperature of the emitter structure is extrapolated between different temperature measurements. The extrapolation of the temperature is based on features of the laser device determined during the calibration phase. For example, during the calibration phase the temperature of the emitter structure is measured for different amounts of power provided to the emitter structure. Thus, if a similar amount of power is provided to the emitter structure as in the calibration phase, the temperature of the emitter structure is assumed to be similar as in the calibration phase.

Once the temperature of the emitter structure is extrapolated, it is assumed that the emitter structure has the extrapolated temperature. In a next step, the extrapolated temperature can be compared to temperatures at which LIV curves were recorded for the emitter structure in the calibration phase. The temperature of the calibration phase that is the closest to the extrapolated temperature can be determined. From the LIV curve for this temperature of the calibration phase it can be determined which amount of power or current is required to reach the target intensity. This amount of power is the second amount of power that is provided to the emitter structure in a next step.

The method described herein therefore enables to provide the target intensity with an improved accuracy. Deviations from the target intensity due to temperature changes of the emitter structure are reduced. Therefore, the laser device can be operated with an improved accuracy.

According to at least one embodiment of the method for operating a laser device, the second amount of power is composed of at least one component, where the component is equal to the sum of the output power of the emitter structure when emitting laser radiation of the target intensity and the thermal power of the emitter structure at the extrapolated temperature. The second amount of power can be composed of several components. Each component can be a component of power. This can mean, that each component relates to a certain amount of power. The laser radiation emitted by the emitter structure has an output power. Once the emitter structure is provided with power, this power is converted into electromagnetic radiation and thermal energy. This leads to the emitter structure having a certain temperature. The thermal power of the emitter structure relates to the amount of power provided to the emitter structure that is converted into thermal energy. The calculation of the component of the second amount of power is thus based on the assumption that the power provided to the emitter structure is converted into thermal energy and electromagnetic radiation. It is also possible that the second amount of power has at least one further component. This further component can be determined based on assumptions about the processes in the laser device. For example, the further component can take into account the ambient temperature around the laser device and/or the temperature of neighboring emitter structures. This means, the calculation of the second amount of power is at least based on the assumption that the power provided to the emitter structure is converted into thermal energy and electromagnetic radiation. Already with this assumption and the corresponding calculation of the second amount of power, the accuracy of providing a target intensity can be increased. The accuracy of providing the target intensity can be further increased by taking into account further assumptions about the processes in the laser device.

According to at least one embodiment of the method for operating a laser device, the second amount of power is given by or proportional to the sum of the output power of the emitter structure when emitting laser radiation of the target intensity and the thermal power of the emitter structure at the extrapolated temperature. The calculation of the second amount of power is therefore based on the assumption that the power provided to the emitter structure is converted into thermal energy and electromagnetic radiation. Already with this assumption and the corresponding calculation of the second amount of power, the accuracy of providing a target intensity can be increased.

According to at least one embodiment of the method for operating a laser device, the thermal power at the extrapolated temperature is given by the difference between a known amount of power provided to the emitter structure and the output power of the emitter structure measured during the calibration phase at the extrapolated temperature. This means, it is assumed that the power provided to the emitter structure is converted into thermal power and output power of the laser radiation emitted by the emitter structure. During the calibration phase different known amounts of power can be provided to the emitter structure. At the same time the output power and the temperature of the emitter structure can be measured. The measured values can be saved in a database. The values saved in the database can be employed by the algorithm for extrapolating the temperature of the emitter structure. By extrapolating the temperature of the emitter structure the accuracy of providing laser radiation of the target intensity can be increased.

According to at least one embodiment of the method for operating a laser device, the temperature of the emitter structure is measured. The temperature of the emitter structure can be measured during operation of the laser device or the emitter structure. It is also possible that the temperature of the emitter structure is measured during a time when the emitter structure does not emit laser radiation. The temperature of the emitter structure can be measured with a temperature sensor or a thermistor. The temperature sensor or the thermistor can be arranged within the laser device or outside of the laser device. Measuring the temperature of the emitter structure has the advantage that the power provided to the emitter structure can be chosen in such a way that the emitter structure emits laser radiation of the target intensity. As the optical output power of the emitter structure depends on the temperature of the emitter structure, the power required for the target intensity can be determined from LIV curves measured at different temperatures in the calibration phase.

It is also possible that the temperature of the emitter structure is determined by providing a negative current to the emitter structure. Once the emitter structure is provided with a positive current, it is operated in forward direction and electromagnetic radiation can be emitted. Once the emitter structure is provided with a negative current, it is operated in reverse direction. In this situation, the voltage across the emitter structure is proportional to the temperature of the ridge structure. The voltage across the emitter structure can be measured by a sense circuitry connected to the emitter structure. Thus, from the voltage measured by the sense circuitry, the temperature of the emitter structure can be determined. After measuring the temperature, the emitter structure can be employed again for the emission of laser radiation. During the time that the emitter structure is provided with a negative current, the emitter structure disconnected from the driving circuit. It is also possible that the temperature of the emitter structure is determined by providing a positive current to the emitter structure. The positive current is preferably very small, for example less than 0.5 A. Also in this case the voltage across the emitter structure is proportional to the temperature of the ridge structure. Thus, the temperature can be determined in the same way as described for the negative current.

It is also possible that for determining the temperature of the emitter structure, a further emitter structure is employed. The further emitter structure can be provided with a negative current in the same way as described above for the emitter structure. The further emitter structure can be arranged adjacent to the emitter structure. Thus, it is assumed that the temperature determined for the further emitter structure is similar to the temperature of the emitter structure. The further emitter structure can be a dummy emitter structure that is not employed for the emission of laser radiation.

According to at least one embodiment of the method for operating a laser device, the temperature of the emitter structure is measured during times that are not employed for imaging in an imaging process. An imaging process can be a process where an image is projected by the laser device. The image can for example be projected by scanning over an area. Times that are not employed for imaging can be times where no part of the image is provided by the laser device. This can for example be dark times. Another example are the times during which optical elements of the laser device change their direction of movement. These optical elements can be mirrors for projecting the emitted laser radiation. These optical elements require time to change their direction of movement in the projection process. This time is usually not employed to project the image. Therefore, this time can be employed for measuring the temperature of the emitter structure. Thus, the time during the imaging process is used efficiently.

According to at least one embodiment of the method for operating a laser device, during the calibration phase light-current-voltage (LIV) curves are measured for the emitter structure for at least two different temperatures of the emitter structure. During the calibration phase LIV curves can be measured for the emitter structure for a plurality of different temperatures. During the calibration phase LIV curves can be measured for the emitter structure for different temperatures, wherein each two neighboring temperatures differ from each other by 20° C. at most or 10° C. at most. The LIV curves measured during the calibration phase can be saved in a database. The measured LIV curves can advantageously be employed for extrapolating the temperature of the emitter structure. It is also possible that during the calibration phase the wall plug efficiency of the emitter structure is determined for at least two different temperatures of the emitter structure. The wall plug efficiency can be determined for the same conditions as the LIV curves.

According to at least one embodiment of the method for operating a laser device, the steps of extrapolating the temperature of the emitter structure and providing the emitter structure with a second amount of power are carried out a plurality of times for different second amounts of power. This can mean, that during a time frame in which the emitter structure emits laser radiation, the temperature of the emitter structure is extrapolated for a plurality of times. After each extrapolation the required second amount of power is determined and provided to the emitter structure. It is possible that the temperature of the emitter structure is measured during this time frame in which the emitter structure emits laser radiation. It is also possible that the steps of extrapolating the temperature of the emitter structure and providing the emitter structure with a second amount of power are carried out a plurality of times and the temperature of the emitter structure is not measured during this time. By carrying out these steps a plurality of times, the accuracy of providing laser radiation of a target intensity is increased.

According to at least one embodiment of the method for operating a laser device, a repetition rate for extrapolating the temperature of the emitter structure is higher than a repetition rate for measuring the temperature of the emitter structure. This can mean, that the temperature of the emitter structure is extrapolated more often during a timeframe than the temperature of the emitter structure is measured. This is because the extrapolation of the temperature can be carried out faster or at a higher frequency than measuring the temperature of the emitter structure. For example, the temperature of the emitter structure can be extrapolated at a repetition rate of at least 10 MHz and at most 800 MHZ. It is also possible that the temperature of the emitter structure is extrapolated at a repetition rate of at least 50 MHz and at most 500 MHz. The higher repetition rate for extrapolating the temperature of the emitter structure enables to increase the accuracy of providing laser radiation of a target intensity.

According to at least one embodiment of the method for operating a laser device, the second amount of power is the sum of power provided by a first power source of the driving circuit and power provided by a second power source of the driving circuit. The first power source and the second power source can each be a current source. The first power source and the second power source can be controlled independently of each other. This enables to provide different components of the second amount of power by different power sources.

According to at least one embodiment of the method for operating a laser device, extrapolating the temperature of the emitter structure comprises receiving a future target intensity. The future target intensity can be the target intensity that is to be provided after providing the target intensity. The algorithm for extrapolating the temperature of the emitter structure can take into account the future target intensity. This has the advantage, that the accuracy of extrapolating the temperature of the emitter structure can be increased. If for example the future target intensity is lower than the target intensity, the emitter structure will cool down when providing the future target intensity. Thus, the second amount of power can be calculated based on this information.

According to at least one embodiment of the method for operating a laser device, the ambient temperature around the laser device is measured. The ambient temperature around the laser device can be measured with a temperature sensor or thermistor. The laser device can comprise the temperature sensor or thermistor. It is also possible that the ambient temperature is measured with a device outside of the laser device. Measuring the ambient temperature has the advantage that the ambient temperature can be taken into account for extrapolating the temperature of the emitter structure since the ambient temperature has an impact on the temperature of the emitter structure.

According to at least one embodiment of the method for operating a laser device, extrapolating the temperature of the emitter structure comprises receiving the measured ambient temperature. The algorithm for extrapolating the temperature of the emitter structure can thus take into account the ambient temperature. This has the advantage, that the accuracy of extrapolating the temperature of the emitter structure can be increased as the ambient temperature has an impact on the temperature of the emitter structure.

According to at least one embodiment of the method for operating a laser device, during the calibration phase the thermal impedance of the emitter structure is determined. This can mean, that during the calibration phase it is measured how much heat is dissipated by the emitter structure. The thermal impedance of the emitter structure can be determined for different temperatures of the emitter structure. It is also possible that the thermal impedance of the emitter structure is calculated or simulated in the calibration phase. Extrapolating the temperature of the emitter structure can comprise taking into account the thermal impedance of the emitter structure. With this, the accuracy of extrapolating the temperature of the emitter structure can be increased.

According to at least one embodiment of the method for operating a laser device, the laser device comprises at least one further emitter structure and the method is carried out separately for the emitter structure and the further emitter structure. The further emitter structure can have the same setup and/or the same features as the emitter structure. The further emitter structure can be configured to emit laser radiation of a wavelength that is different from the wavelength of laser radiation emitted by the emitter structure during operation. That the method is carried out separately for the emitter structure and the further emitter structure can mean, that the temperature of the emitter structure is extrapolated and the temperature of the further emitter structure is extrapolated. The temperature of the emitter structure can be extrapolated separately from the temperature of the further emitter structure. However, it is possible that for extrapolating the temperature of the emitter structure, the temperature of the further emitter structure is taken into account. It is also possible that for extrapolating the temperature of the further emitter structure, the temperature of the emitter structure is taken into account. Thus, the method advantageously enables to extrapolate the temperature of different emitter structures of a laser device.

According to at least one embodiment of the method for operating a laser device, extrapolating the temperature of the emitter structure comprises receiving the extrapolated temperature of the further emitter structure. This can mean, that for extrapolating the temperature of the emitter structure, the extrapolated temperature of the further emitter structure is taken into account. Since the emitter structure and the further emitter structure are arranged in the same laser device, the temperature and the extrapolated temperature of the further emitter structure have an impact on the temperature of the emitter structure. By taking into account this impact, the accuracy of extrapolating the temperature of the emitter structure is increased.

According to at least one embodiment of the method for operating a laser device, extrapolating the temperature of the emitter structure comprises receiving the information which amount of power is provided to the further emitter structure. The amount of power provided to the further emitter structure has an impact on the temperature of the further emitter structure and thus also on the temperature of the emitter structure. By taking into account this impact, the accuracy of extrapolating the temperature of the emitter structure is increased.

Furthermore, a laser device is provided. The laser device can preferably be operated by the method for operating a laser device described herein. This means all features disclosed for the method for operating a laser device are also disclosed for the laser device and vice-versa.

According to at least one embodiment of the laser device, the laser device comprises at least one emitter structure that is configured to emit laser radiation during operation.

According to at least one embodiment of the laser device, the laser device comprises a driving circuit that is connected with the emitter structure and that is configured to provide the emitter structure with power.

According to at least one embodiment of the laser device, the laser device comprises an extrapolation unit that is configured to extrapolate the temperature of the emitter structure. The extrapolation unit can comprise a processor that is configured to run an algorithm for extrapolating the temperature of the emitter structure.

According to at least one embodiment of the laser device, the laser device comprises a control unit that is configured to control the power provided by the driving circuit. The control unit can be connected with the driving circuit. It is also possible that the control unit is comprised by the driving circuit. The control unit can be configured to control the amount of power provided by the driving circuit. This can mean, that the control unit is configured to control how much power the driving circuit provides. The control unit can be connected with the extrapolation unit.

According to at least one embodiment of the laser device, extrapolating the temperature of the emitter structure comprises receiving a temperature value measured for the emitter structure provided with a known first amount of power during a calibration phase. This can mean, that during the calibration phase the first amount of power is provided to the emitter structure by the driving circuit. For this situation, the temperature of the emitter structure is measured during the calibration phase.

According to at least one embodiment of the laser device, controlling the power provided by the driving circuit comprises providing the emitter structure with a second amount of power by the driving circuit, wherein the second amount of power corresponds to the power required for the emitter structure emitting a target intensity of laser radiation at the extrapolated temperature.

According to at least one embodiment of the laser device, the laser device comprises at least one emitter structure that is configured to emit laser radiation during operation, a driving circuit that is connected with the emitter structure and that is configured to provide the emitter structure with power, an extrapolation unit that is configured to extrapolate the temperature of the emitter structure, and a control unit that is configured to control the power provided by the driving circuit, wherein extrapolating the temperature of the emitter structure comprises receiving a temperature value measured for the emitter structure provided with a known first amount of power during a calibration phase, and controlling the power provided by the driving circuit comprises providing the emitter structure with a second amount of power by the driving circuit, wherein the second amount of power corresponds to the power required for the emitter structure emitting a target intensity of laser radiation at the extrapolated temperature.

The laser device has the same advantages as described with respect to the method for operating a laser device. It is thus possible to extrapolate the temperature of the emitter structure with the laser device and to adapt the amount of power provided to the emitter structure during operation according to the extrapolated temperature. This enables to operate the laser device with an increased accuracy.

The laser device can be a laser device for displaying images. Thus, the laser device can be employed in a display. The laser device can be a laser beam scanning projector. This can mean, that the laser device is configured to project pixels of an image after one another. The target intensity can be different for different pixels. The laser device can be a single-ridge laser or a multi-ridge laser.

According to at least one embodiment of the laser device, the laser device comprises a temperature sensor or a thermistor. The temperature sensor or thermistor can be arranged adjacent to the emitter structure. Thus, the temperature sensor or thermistor can be configured to measure the temperature of the emitter structure. This advantageously enables to monitor the temperature of the emitter structure during operation.

With FIG. 1 an exemplary embodiment of the method for operating a laser device 20 is described. A first step S1 of the method is a calibration phase. In the calibration phase an emitter structure 21 of the laser device 20 is provided with a first amount of power by a driving circuit 22 of the laser device 20. The emitter structure 21 is configured to emit laser radiation during operation. At the same time the temperature of the emitter structure 21 is measured. The temperature of the emitter structure 21 can be measured by a temperature sensor 28 or thermistor 29 of the laser device 20. The measured temperature can be saved in a database 30 as a temperature value. It is also possible that during the calibration phase LIV curves and/or the wall plug efficiency are measured for the emitter structure 21 for at least two different temperatures of the emitter structure 21. It is also possible that during the calibration phase the thermal impedance of the emitter structure 21 is determined.

In a second step S2 of the method the emitter structure 21 is provided with the first amount of power by the driving circuit 22. The second step S2 takes place after the calibration phase.

In a third step S3 of the method the temperature of the emitter structure 21 is extrapolated. Extrapolating the temperature of the emitter structure 21 comprises receiving the temperature value measured for the emitter structure 21 provided with the first amount of power during the calibration phase.

In a fourth step S4 of the method the emitter structure 21 is provided with a second amount of power by the driving circuit 22. The second amount of power corresponds to the power required for the emitter structure 21 emitting a target intensity of laser radiation at the extrapolated temperature. The second amount of power can be composed of at least one component, where the component is equal to the sum of the output power of the emitter structure 21 when emitting laser radiation of the target intensity and the thermal power of the emitter structure 21 at the extrapolated temperature. The thermal power at the extrapolated temperature can be given by the difference between a known amount of power provided to the emitter structure 21 and the output power of the emitter structure 21 measured during the calibration phase at the extrapolated temperature.

The steps of extrapolating the temperature of the emitter structure 21 and providing the emitter structure 21 with a second amount of power, this means the third and the fourth step S3, S4, can be carried out a plurality of times for different second amounts of power. This is shown with the arrow on the right side in FIG. 1.

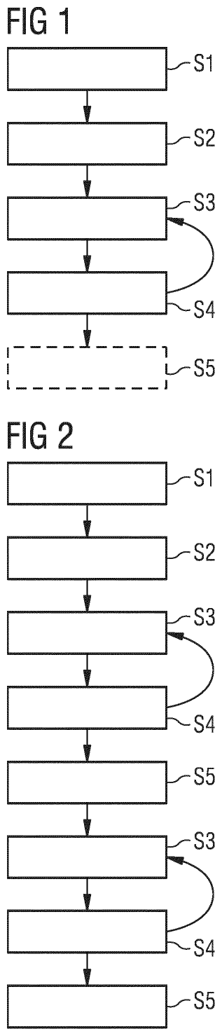

In an optional fifth step S5 of the method the temperature of the emitter structure 21 is measured. This means, the temperature of the emitter structure 21 is also measured after the calibration phase. It is possible that the extrapolation of the temperature is carried out between different temperature measurements of the emitter structure 21. This is shown in FIG. 2.

With FIG. 2 another exemplary embodiment of the method for operating a laser device 20 is described. In the method of FIG. 2 the first to the fifth step S1-S5 shown in FIG. 1 are carried out. The third step S3 and the fourth step S4 can be carried out a plurality of times after one another before the fifth step S5 is carried out. After the fifth step S5, the third step S3 follows again. After the third step S3, the fourth step S4 follows again. The third step S3 and fourth step S4 can be carried out a plurality of times after one another before the fifth step S5 is carried out again. A repetition rate for extrapolating the temperature of the emitter structure 21 is thus higher than a repetition rate for measuring the temperature of the emitter structure 21.

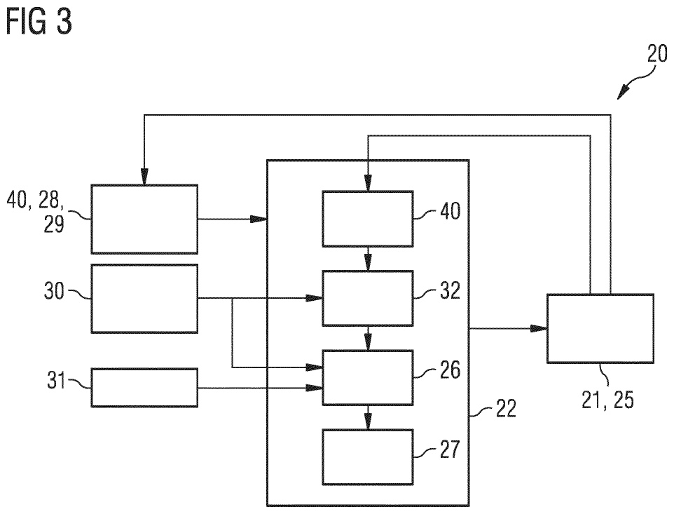

With FIG. 3 another exemplary embodiment of the method for operating a laser device 20 is described. The laser device 20 comprises at least one sensor 40. The sensor 40 can be a temperature sensor 28 or thermistor 29. Additionally, the laser device 20 can comprise a photo detector or a photodiode. The sensors 40 are configured to provide the measured data to the driving circuit 22. This is shown by an arrow between one box representing the sensors 40 and the driving circuit 22. It is also possible that a sensor outside of the laser device 20 is configured to provide data to the driving circuit 22. The sensor outside of the laser device 20 can be configured to measure the ambient temperature around the laser device 20.

The laser device 20 can further comprise a database 30 where data recorded during the calibration phase is saved. The data of the database 30 can be provided to the driving circuit 22 which is shown by an arrow between the database 30 and the driving circuit 22. The laser device 20 can further be connected with a data device 31 that comprises the information which target intensity is to be provided. This can mean, that the data device 31 comprises information about an image 34 or a video to be displayed by the laser device 20. The data device 31 can comprise the information at which point in time which target intensity is to be provided by the laser device 20. Information of the data device 31 is provided to the driving circuit 22 which is shown by an arrow between the data device 31 and the driving circuit 22. It is also possible that a future target intensity is provided by the data device 31 to the driving circuit 22. This enables that extrapolating the temperature of the emitter structure 21 comprises receiving a future target intensity.

The driving circuit 22 is connected with the emitter structure 21. The emitter structure 21 can also be configured to provide data to the driving circuit 22 which is shown by an arrow from the emitter structure 21 to the driving circuit 22. For example, the temperature of the emitter structure 21 can be measured by providing a negative current to the emitter structure 21. The driving circuit 22 can be configured to measure the voltage across the emitter structure 21 in this situation. In this way, the temperature of the emitter structure 21 can be determined. The emitter structure 21 can also be connected with one or more sensors 40 of the laser device 20 which is shown by an arrow from the emitter structure 21 to the box representing the sensors 40. It is also possible, that at least one temperature sensor 28 of the laser device 20 is configured to measure the temperature of the emitter structure 21.

The driving circuit 22 as well can comprise at least one sensor 40 of the laser device 20. The driving circuit 22 can comprise an estimation unit 32 that is configured to estimate the laser conditions. The laser conditions can comprise at least one of the current amplitude, continuous-wave or pulsed operation, timing of current pulses (on time, off time), repetition rate. The estimation unit 32 can be configured to estimate the laser conditions based on data recorded by the at least one sensor 40 of the laser device 20 and data recorded during the calibration phase.

The driving circuit 22 further comprises an extrapolation unit 26 that is configured to extrapolate the temperature of the emitter structure 21. The extrapolation can be based on information received from the estimation unit 32, the database 30 and the data device 31. Extrapolating the temperature of the emitter structure 21 can also comprise receiving the measured ambient temperature.

The driving circuit 22 further comprises a control unit 27 that is configured to control the power provided by the driving circuit 22 by providing the second amount of power to the emitter structure 21.

The laser device 20 can comprise at least one further emitter structure 25 and the method can be carried out separately for the emitter structure 21 and the further emitter structure 25. In this case, extrapolating the temperature of the emitter structure 21 can comprise receiving the extrapolated temperature of the further emitter structure 25.

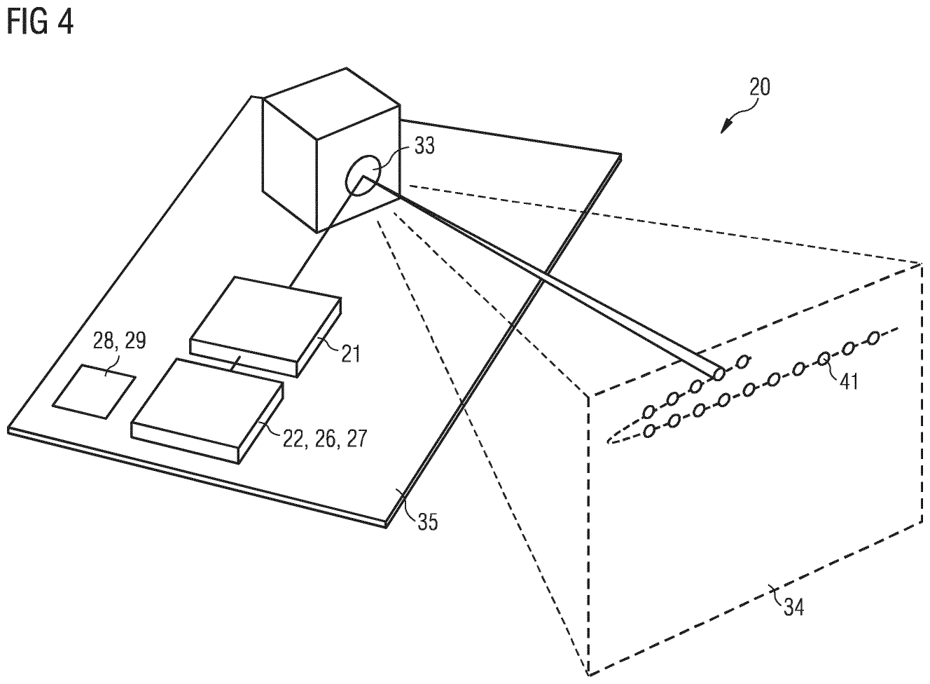

FIG. 4 shows an exemplary embodiment of the laser device 20. The laser device 20 comprises at least one emitter structure 21 that is configured to emit laser radiation during operation and a driving circuit 22 that is connected with the emitter structure 21 and that is configured to provide the emitter structure 21 with power. The driving circuit 22 comprises an extrapolation unit 26 that is configured to extrapolate the temperature of the emitter structure 21, and a control unit 27 that is configured to control the power provided by the driving circuit 22. Controlling the power provided by the driving circuit 22 comprises providing the emitter structure 21 with a second amount of power by the driving circuit 22, wherein the second amount of power corresponds to the power required for the emitter structure 21 emitting a target intensity of laser radiation at the extrapolated temperature.

The emitter structure 21 and the driving circuit 22 are arranged on a common carrier 35. On the carrier 35 also a mirror 33 is arranged. The mirror 33 can be configured to be moved in at least one direction. By moving the mirror 33, laser radiation emitted by the emitter structure 21 can be projected to different positions so that an image 34 is projected. The image 34 can comprise a plurality of pixels 41. The laser device 20 further comprises a temperature sensor 28 or a thermistor 29.

The temperature of the emitter structure 21 can be measured by the temperature sensor 28 or the thermistor 29 during times that are not employed for imaging in an imaging process. These times can for example be the times during which the mirror 33 changes its direction of movement. In the image 34 these are the positions at the edges of the image 34 where the dotted line in FIG. 4 changes its direction.

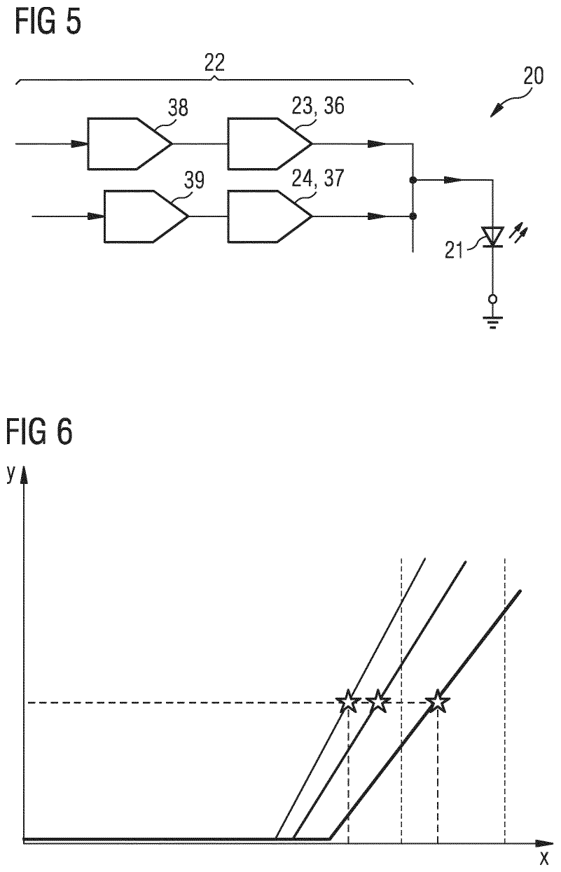

FIG. 5 shows a part of another exemplary embodiment of the laser device 20. The driving circuit 22 of the laser device 20 comprises a first gain digital-to-analog converter (DAC) 38 and a second gain DAC 39. The configuration of the first gain DAC 38 and the second gain DAC 39 is static which means that it is not changed during operation of the laser device 20. However, the configuration of the first gain DAC 38 and the second gain DAC 39 can be changed in a re-calibration process, for example to compensate for aging effects. The first gain DAC 38 and the second gain DAC 39 are each provided with a current during operation of the laser device 20.

The driving circuit 22 further comprises a first DAC 36 and a second DAC 37. The first DAC 36 is connected with the first gain DAC 38. The first DAC 36 is configured to provide a current that can be in most cases or in every case below the threshold current for lasing. The current provided by the first DAC 36 can be a direct current, a pulsed current or a combination of the two. The second DAC 37 is connected with the second gain DAC 39. The second DAC 37 is configured to provide current pulses, for example in the ns range. Thus, the sum of the current that is provided by the first DAC 36 and the second DAC 37 is provided to the emitter structure 21 during operation of the laser device 20.

The least significant bit of the first DAC 36 can be controlled by the first gain DAC 38. The least significant bit of the second DAC 37 can be controlled by the second gain DAC 39. Thus, the first gain DAC 38 is employed to configure the electrical range of the first DAC 36 and the second gain DAC 39 is employed to configure the electrical range of the second DAC 37. The first gain DAC 38 and the second gain DAC 39 are configured in such a way that the laser device 20 can be operated in a predefined temperature range.

The current that is required to be provided by the second DAC 37 is determined after each extrapolation of the temperature of the emitter structure 21. Subsequently, the second DAC 37 is operated to provide the required current. The extrapolation of the temperature of the emitter structure 21 and providing the required current by the second DAC 37 can be carried out at a rate of at least 10 MHz and at most 800 MHZ.

The current that is required to be provided by the first DAC 36 can be determined after each time that the temperature of the emitter structure 21 is measured. Subsequently, the first DAC 36 is operated to provide the required current. The temperature of the emitter structure 21 can be measured at a rate of at least 50 kHz and at most 1 MHZ.

The second amount of power is thus the sum of the power provided by a first power source 23 of the driving circuit 22, namely the first DAC 36, and the power provided by a second power source 24 of the driving circuit 22, namely the second DAC 37. This means, the second amount of power comprises at least two components that are provided by different DACs, namely the first DAC 36 and the second DAC 37. Only the current level of the second DAC 37 is adapted according to the extrapolated temperature of the emitter structure 21. The current level of the first DAC 36 is adapted according to the measured temperature of the emitter structure 21.

The optical pulse energy of a laser pulse provided by the emitter structure 21 depends on the current level provided by first DAC 36, the current level provided by the second DAC 37 and the pulse length provided by the second DAC 37. FIG. 6 schematically shows the output power of a laser device 20 at different temperatures. On the x-axis the current provided to the emitter structure 21 of a laser device 20 is plotted. On the y-axis the optical power of laser radiation provided by the emitter structure 21 is plotted for three different temperatures of the emitter structure 21. With increasing temperature of the emitter structure 21, the threshold current for lasing increases. Furthermore, the slope efficiency, this means the slope of the curve shown in FIG. 6, changes with increasing temperature. Thus, for achieving a target output power that is marked with the dashed line, an increasing current is required to be provided to the emitter structure 21 with increasing temperature.

In the laser device 20 described herein, the first DAC 36 can be configured to provide a current that is equal to the threshold current at a present temperature. The second DAC 37 can be configured to provide the remaining part of the current that is required to achieve a target output power or target intensity. This means, the first DAC 36 can be employed to correct the laser threshold current for a changing temperature of the emitter structure 21 and the second DAC 37 can be employed to correct the slope efficiency for a changing temperature of the emitter structure 21. As the threshold current and the slope efficiency do not change linearly with the temperature, but non-linear, a polynomial fitting is required for obtaining the currents that are to be provided by the first DAC 36 and the second DAC 37.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art. The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

### REFERENCES

20 laser device
21 emitter structure
22 driving circuit
23 first power source
24 second power source
25 further emitter structure
26 extrapolation unit
27 control unit
28 temperature sensor
29 thermistor
30 database
31 data device
32 estimation unit
33 mirror
34 image
35 carrier
36 first DAC
37 second DAC
38 first gain DAC
39 second gain DAC
40 sensor
41 pixel
S1 first step
S2 second step
S3 third step
S4 fourth step
S5 fifth step

1. Method for operating a laser device, the method comprising:
providing an emitter structure of the laser device with a first amount of power by a driving circuit of the laser device, wherein the emitter structure is configured to emit laser radiation during operation;
extrapolating a temperature of the emitter structure, wherein extrapolating the temperature of the emitter structure comprises receiving a temperature value measured for the emitter structure provided with the first amount of power during a calibration phase; and
providing the emitter structure with a second amount of power by the driving circuit, wherein the second amount of power corresponds to the power required for the emitter structure emitting a target intensity of laser radiation at the extrapolated temperature, wherein
the temperature of the emitter structure is measured during times that are not employed for imaging in an imaging process.

2. Method for operating a laser device according to claim 1, wherein the second amount of power is composed of at least one component, where the component is equal to a sum of an output power of the emitter structure when emitting laser radiation of the target intensity and a thermal power of the emitter structure at the extrapolated temperature.

3. Method for operating a laser device according to claim 2, wherein the thermal power at the extrapolated temperature is given by a difference between a known amount of power provided to the emitter structure and the output power of the emitter structure measured during the calibration phase at the extrapolated temperature.

4. Method for operating a laser device according to claim 1, wherein the temperature of the emitter structure is measured.

5. (canceled)

6. Method for operating a laser device according to claim 1, the method further comprising measuring, during the calibration, phase light-current-voltage curves for the emitter structure for at least two different temperatures of the emitter structure.

7. Method for operating a laser device according to claim 1, wherein the steps of extrapolating the temperature of the emitter structure and providing the emitter structure with a second amount of power are carried out a plurality of times for different second amounts of power.

8. Method for operating a laser device according to claim 1, wherein a repetition rate for extrapolating the temperature of the emitter structure is higher than a repetition rate for measuring the temperature of the emitter structure.

9. Method for operating a laser device according to claim 1, wherein the second amount of power is a sum of power provided by a first power source of the driving circuit and power provided by a second power source of the driving circuit.

10. Method for operating a laser device according to claim 1, wherein extrapolating the temperature of the emitter structure comprises receiving a future target intensity.

11. Method for operating a laser device according to claim 1, the method further comprising measuring an ambient temperature around the laser device.

12. Method for operating a laser device according to claim 11, wherein extrapolating the temperature of the emitter structure comprises receiving the measured ambient temperature.

13. Method for operating a laser device according to the claim 1, wherein during the calibration phase a thermal impedance of the emitter structure is determined.

14. Method for operating a laser device according to claim 1, wherein the laser device comprises at least one further emitter structure and the method is carried out separately for the emitter structure and the further emitter structure.

15. Method for operating a laser device according to claim 13, wherein extrapolating the temperature of the emitter structure comprises receiving the extrapolated temperature of the further emitter structure.

16. Laser device comprising:
at least one emitter structure that is configured to emit laser radiation during operation;
a driving circuit that is connected with the emitter structure and that is configured to provide the emitter structure with power;
an extrapolation unit that is configured to extrapolate the temperature of the emitter structure; and
a control unit that is configured to control the power provided by the driving circuit, wherein:
extrapolating a temperature of the emitter structure comprises receiving a temperature value measured for the emitter structure provided with a known first amount of power during a calibration phase;
controlling the power provided by the driving circuit comprises providing the emitter structure with a second amount of power by the driving circuit, wherein the second amount of power corresponds to power required for the emitter structure emitting a target intensity of laser radiation at the extrapolated temperature; and
the laser device comprises a temperature sensor or a thermistor that is configured to measure the temperature of the emitter structure during times that are not employed for imaging in an imaging process.

17. (canceled)

18. Method for operating a laser device, the method comprising:
providing an emitter structure of the laser device with a first amount of power by a driving circuit of the laser device, wherein the emitter structure is configured to emit laser radiation during operation;
extrapolating a temperature of the emitter structure, wherein extrapolating the temperature of the emitter structure comprises receiving a temperature value measured for the emitter structure provided with the first amount of power during a calibration phase; and
providing the emitter structure with a second amount of power by the driving circuit, wherein the second amount of power corresponds to the power required for the emitter structure emitting a target intensity of laser radiation at the extrapolated temperature.
